(19) United States
(12) Patent Application Publication
(10) Pub. No.: US 2014/0076494 A1
(43) Pub. Date: Mar. 20, 2014

(54) PROCESSING SYSTEM

(71) Applicant: Tokyo Electron Limited, Minato-ku (JP)

(72) Inventors: Tetsuya MIYASHITA, Yamanashi (JP); Kaoru YAMAMOTO, Yamanashi (JP)

(73) Assignee: Tokyo Electron Limited, Minato-ku (JP)

(21) Appl. No.: 14/027,367

(22) Filed: Sep. 16, 2013

(30) Foreign Application Priority Data
Sep. 18, 2012 (JP) 2012-204268

(51) Int. Cl. H01L 21/677

(52) U.S. Cl. CPC H01L 21/67703
USPC 156/345.31; 118/719

(57) ABSTRACT

A processing system includes a transfer chamber having therein a transfer unit for transferring a substrate and at least one processing unit connected to the transfer chamber. The transfer chamber is maintained in a vacuum state. The processing unit is configured to perform a processing on a substrate. The processing unit includes a first chamber in which a first processing is performed on a substrate, and a second chamber detachably installed in the first chambers. A second processing is performed on a substrate in the second chamber installed in the first chamber. Wall portions of the first chamber and the second chamber are maintained at different temperatures.

### CROSS-REFERENCE TO RELATED APPLICATION

This application claims priority to Japanese Patent Application No. 2012-204268 filed on Sep. 18, 2012, the entire contents of which are incorporated herein by reference.

### FIELD OF THE INVENTION

The present invention relates to a processing system for performing film formation or the like on a substrate to be processed, e.g., a semiconductor wafer.

### BACKGROUND OF THE INVENTION

A vacuum processing such as film formation, etching or the like which is performed on a semiconductor wafer (hereinafter, simply referred to as “wafer”) as a substrate to be processed in a vacuum atmosphere is widely used in a semiconductor device manufacturing process. Recently, a cluster tool type multi-chamber vacuum processing system (see, e.g., Japanese Patent Application Publication No. 2000-208589) attracts attention in view of efficiency of vacuum processing and reduction of oxidation or contamination. In the multi-chamber vacuum processing system, a plurality of processing units is connected to a transfer chamber maintained in a vacuum state, and a wafer can be transferred to each of the processing units by a transfer device provided in the transfer chamber.

In the multi-chamber processing system, the transfer chamber and the chambers of the processing units may be manufactured integrally for the purpose of reducing costs, footprint and seal.

However, the processing unit may have a hot wall type in which a chamber wall itself is heated to reduce deposition or prevent adhesion of by-products. In that case, since the integrated chamber is entirely heated, the number of heat insulating members of the transfer chamber side or the number of heat-resistant components is increased, which causes problems in terms of technique and cost. On the contrary, when the chamber wall itself needs to be cooled to an extremely low temperature, the integrated chamber is entirely cooled, which is not reasonable.

Further, in the case of using the integrated chamber and other cases, chambers whose wall temperatures are different, such as a cold wall type and a hot wall type, need to be selectively used. However, the conventional multi-chamber processing system cannot deal with such a case.

### SUMMARY OF THE INVENTION

In view of the above, the present invention provides a processing system capable of selectively using chambers whose wall temperatures are different. Further, the present invention provides a processing system capable of reducing thermal effects from the chambers of the processing units to the transfer chamber or the like.

In accordance with the first aspect of the invention, there is provided a processing system including: a transfer chamber having therein a transfer unit for transferring a substrate, the transfer chamber being maintained in a vacuum state; and at least one processing unit connected to the transfer chamber, the processing unit configured to perform a processing on a substrate, wherein the processing unit includes: a first chamber in which a first processing is performed on a substrate; and a second chamber detachably installed in the first chambers, a second processing being performed on a substrate in the second chamber installed in the first chamber, wherein wall portions of the first chamber and the second chamber are maintained at different temperatures.

With such configuration, the first chamber and the transfer chamber are provided as one unit. The first chamber has a wall that is not heated or cooled so as not to inflict thermal effect on the transfer chamber, and the second chamber has a wall that can be heated or cooled. In that case, the second chamber is preferably installed while being insulated from the first chamber. Further, when the second chamber is installed, the first chamber and the second chamber are separated from each other by a space therebetween, and a vacuum insulation is obtained by setting the space in a vacuum state. The predetermined processing may be performed in a vacuum state.

In accordance with the second aspect of the invention, there is provided a processing system including: a transfer chamber having therein a transfer unit for transferring a substrate, the transfer chamber being maintained in a vacuum state; and at least one processing unit connected to the transfer chamber, the processing unit configured to perform a processing on a substrate, wherein the processing unit includes: a first chamber in which a first processing is performed on the substrate in a state where a wall portion of the first chamber is not subjected to heating or cooling which inflicts thermal effect on the transfer chamber; and a second chamber detachably installed in the first chamber, a second processing being performed on a substrate in the second chamber installed in the first chamber in a state where a wall portion of the second chamber is heated or cooled, and wherein the first chamber is formed integrally with the transfer chamber, and the second chamber is installed in the first chamber in an adiabatic state.

With such configuration, the predetermined processing is performed in a vacuum state. When the second chamber is installed, the first chamber and the second chamber are separated from each other by a space therebetween. The vacuum insulation is obtained by setting the space in a vacuum state by performing vacuum evacuation during the processing.

### BRIEF DESCRIPTION OF THE DRAWINGS

The objects and features of the present invention will become apparent from the following description of embodiments, given in conjunction with the accompanying drawings, in which:

FIG. 1 is a horizontal cross sectional view showing a schematic structure of a multi-chamber vacuum processing system in accordance with an embodiment of the present invention;

FIG. 2 is a top view showing a integrated chamber in which a chamber of a transfer chamber and chambers of processing units are provided as one unit in the multi-chamber vacuum processing system of FIG. 1;

FIG. 3 is a cross sectional view showing a integrated chamber in which a chamber of a transfer chamber and chambers of processing units are provided as one unit in the multi-chamber vacuum processing system of FIG. 1;

FIG. 4 is a cross sectional view showing a state of the processing unit in the case of performing processing in the chamber of the processing unit.

FIG. 5 is a cross sectional view showing a state in which a heating chamber is installed in the chamber of the processing unit; and

FIG. 6 is a cross sectional view showing a state of the processing unit in the case of performing processing in the heating chamber.

### DETAILED DESCRIPTION OF THE EMBODIMENTS

Hereinafter, an embodiment of the present invention will be described with reference to the accompanying drawings which form a part hereof.

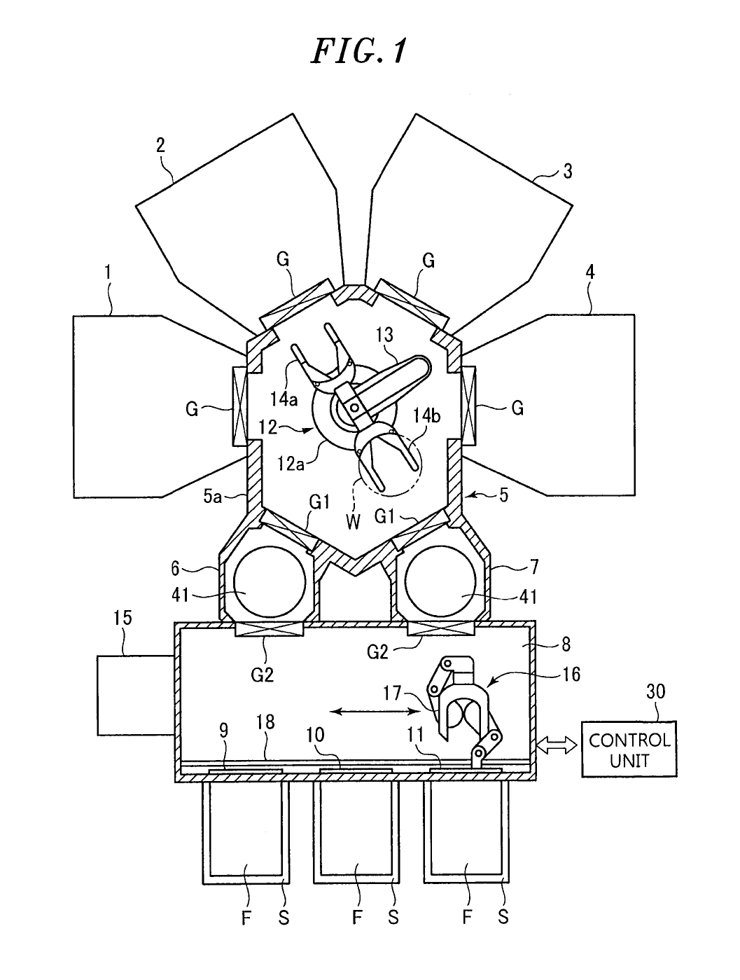

FIG. 1 is a horizontal cross sectional view showing a schematic structure of a multi-chamber vacuum processing system in accordance with an embodiment of the present invention.

The multi-chamber vacuum processing system includes a transfer chamber 5 comprised of a main body 5a having six sidewalls and a hexagonal shape when seen from the top. Four processing units 1 to 4 are respectively connected to four sidewalls of the main body 5a of the transfer chamber 5 via gate valves G. The transfer chamber 5 includes a lid (not shown) provided on the main body 5a. Load-lock chambers 6 and 7 are provided at the remaining two sidewalls of the main body 5a of the transfer chamber 5 via gate valves G1.

A loading/unloading chamber 8 is provided on the opposite side of the load-lock chambers 6, 7 to the transfer chamber 5, and ports 9 to 11 for connecting three FOUPs (Front Opening Unified Pods) capable of accommodating a wafer W as a substrate to be processed are provided on the opposite side of the loading/unloading chamber 8 to the load-lock chambers 6 and 7. Gate valves G2 are provided between the load-lock chambers 6, 7 and the loading/unloading chamber 8.

The processing units 1 to 4 perform vacuum processing, e.g., film formation or etching, on a wafer W as a substrate to be processed.

The processing units 1 to 4 communicate with the transfer chamber 5 by opening the corresponding gate valves G, and are isolated from the transfer chamber 5 by closing the corresponding gate valves G. Further, the load-lock chambers 6, 7 communicate with the transfer chamber 5 by opening the gate valve G1 and are isolated from the transfer chamber 5 by closing the gate valve G1. Moreover, the load-lock chambers 6, 7 communicate with the loading/unloading chamber 8 by opening the gate valve G2, and are isolated from the loading/unloading chamber 8 by closing the gate valve G2.

Provided in the main body 5a of the transfer chamber 5 is a transfer unit 12 for loading and unloading a wafer W into and from the processing units 1 to 4 and the load-lock chambers 6, 7. This transfer unit 12 is disposed at an approximately central portion in the transfer chamber 5, and has a base 12a, a rotatable and extensible/contractible portion 13, and two support arms 14a, 14b for supporting the wafer W, the support arms 14a, 14b being provided at the leading end of the rotatable and extensible/contractible portion 13. The two support arms 14a, 14b are installed at the rotatable and extensible/contractible portion 13 so as to face the opposite directions from each other. The inside of the transfer chamber 5 is maintained at a predetermined vacuum level.

Each of the load-lock chambers 6, 7 has a stage 41 having a cooling function and other functional members (not shown). The load-lock chambers 6, 7 have inner spaces having a small capacity which can be switched between an atmospheric atmosphere and a vacuum atmosphere.

Shutters (not shown) are provided at the respective three ports 9 to 11 of the loading/unloading chamber 8. The FOUPs F, each accommodating a wafer W therein or being empty, are directly attached to the ports 9 to 11 while being mounted on the stage S. The shutters are opened when the FOUPs F are attached, so that the FOUPs F communicate with the loading/unloading chamber 8 while preventing infiltration of exterior air. Provided at a side surface of the loading/unloading chamber 8 is an alignment chamber 15 in which the wafer W is aligned.

Provided in the loading/unloading chamber 8 is a transfer unit 16 for transferring the wafer W between the FOUPs F and the load-lock chambers 6, 7. The transfer unit 16 has a multi-joint arm structure, and can move on a rail along the arrangement direction of the FOUPs F. The transfer unit 16 transfers the wafer W while holding the wafer W on a support arm 17 provided at a leading end thereof.

The multi-chamber vacuum processing system includes a control unit 30 having a micro processor (computer) for controlling each of the units, and each of the units is connected to and controlled by the control unit 30.

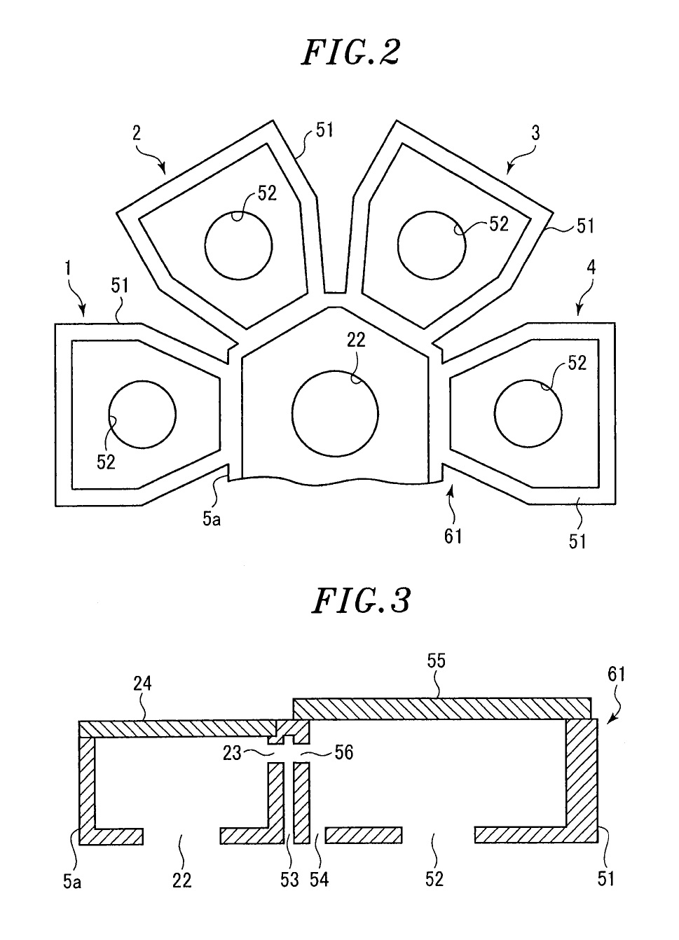

As shown in FIGS. 2 and 3, the processing units 1 to 4 (only one is shown in FIG. 3) have first chambers 51. The first chambers 51 are formed integrally with the main body 5a of the transfer chamber 5, thereby constituting an integrated chamber 61.

A circular hole 22 into which the transfer unit 12 is inserted is formed in the bottom portion of the main body 5a of the transfer chamber 5. Circular holes 52 to which gas exhaust units are installed are formed in the bottom portions of the first chambers 51 of the processing units 1 to 4. Moreover, loading/unloading ports 23 and 56 are respectively formed at connecting portions of the main body 5a of the transfer chamber 5 and the first chambers 51. Formed between the loading/unloading port 23 and the loading/unloading port 56 is a space 53 used for vertical movement of the gate valve. Formed in the bottom portions of the first chambers 51 are holes 54 that are used for vertical movement of the gate valves when a second chamber 81 to be described later is attached. Further, the upper openings of the first chambers 51 and the main body 5a of the transfer chamber 5 are covered by lids 55 and 24, respectively.

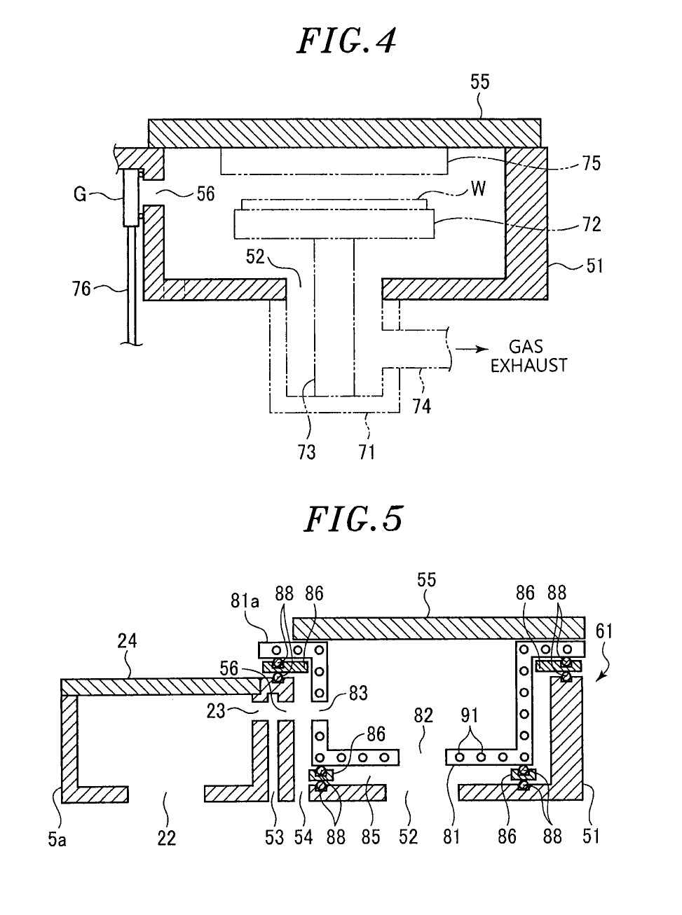

The second chamber 81 to be described later is detachably provided in the first chambers 51 of the processing units 1 to 4. The first chambers 51 may be used as chambers of cold wall type processing units. When it is unnecessary to heat the chamber wall, the second chamber 81 is not installed, and a mounting table 72, a shower head 75 and the like are installed in the first chamber 51 as shown in FIG. 4. Thereafter, the gas exhaust unit is further installed, and a specific processing, e.g., film formation, is performed in the chamber 51. The heating or the cooling of the wall portions of the first chambers 51 which inflicts thermal effect on the transfer chamber 5 is not carried out.

Specifically, the gas exhaust unit is formed by installing a gas exhaust chamber 71 around the lower hole 52 of the first chamber 51 and connecting a valve or a vacuum pump (not shown) to a line 74 connected to the gas exhaust chamber 71. The mounting table 72 having a heater is provided to be supported by a supporting member 73 vertically extending from the bottom portion of the gas exhaust chamber 71 into the first chamber 51, and the shower head 75 for introducing a processing gas into the first chamber 51 is provided at a backside of the lid 55. The processing gas is introduced into the first chamber 51 through a gas inlet port (not shown) formed in the lid 55 and the shower head 75. The loading/unloading port 56 is opened and closed by the gate valve G vertically moving in the space 53. An elevation rod 76 of the gate valve G and a bottom wall (not shown) defining the space 53 are vacuum-sealed, and the hole 54 is also vacuum-sealed.

Accordingly, the processing gas is introduced from the shower head 75 into the first chamber 51 while heating the wafer W on the mounting table 72 in the first chamber 51, and CVD film formation may be performed on the wafer W.

The first chamber 51 is configured such that the second chamber 81 having a unit for heating a wall portion can be installed therein. A hot wall type processing unit is constituted by installing the second chamber 81 in the first chamber 51. Therefore, when the processing needs to be performed while heating the chamber wall, the second chamber 81 is installed in the first chamber 51 as shown in FIG. 5. A heater 91 as the unit for heating the wall portion is buried in the wall portion of the second chamber 81. The second chamber 81 has a suitable size to be installed in the first chamber 51 in an adiabatic state.

The second chamber 81 has a flange 81a formed at an upper portion thereof, and the flange 81a is mounted with an upper end of the first chamber 51 via a heat insulating member 86 such as ULTEM (Registered Trademark). Accordingly, the second chamber 81 is aligned in the first chamber 51. A sealing member 88 is provided between the flange 81a of the second chamber 81 and the heat insulating member 86 and between the heat insulating member 86 and the upper end of the first chamber 51 to make a vacuum-seal.

When the second chamber 81 is installed, a space 85 is formed between the first chamber 51 and the second chamber 81. Therefore, the space therebetween is vacuum insulated by vacuum evacuation. Further, a heat insulating member 86 is provided between the bottom portion of the first chamber 51 and the bottom portion of the second chamber 81 via a sealing member 88.

A hole 82 is formed in a bottom portion of the second chamber 81 so as to correspond to the hole 52 of the first chamber 51. Further, a loading/unloading port 83 is provided at the sidewall of the second chamber 81 so as to correspond to the loading/unloading port 56 of the first chamber 51. The lid 55 is installed to block the upper opening of the second chamber 81, and the processing space is formed in the second chamber 81. As a consequence, it can be used as a chamber of a hot wall type processing unit.

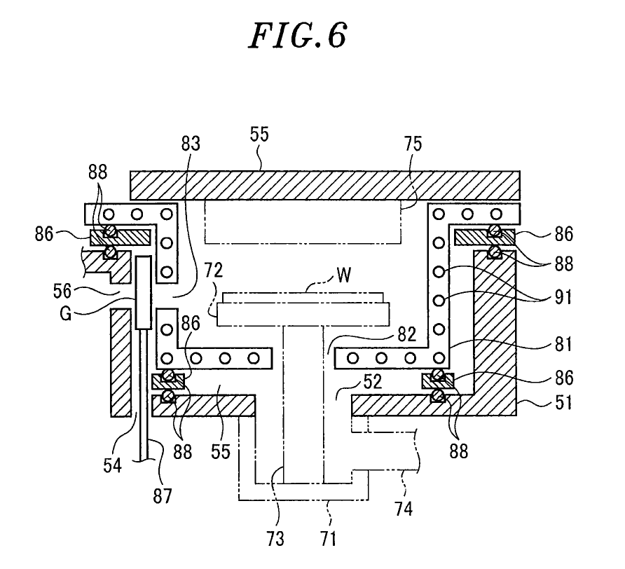

As shown in FIG. 6, the mounting table 72, the shower head 75 and the like are installed in the second chamber 81, and a processing gas is introduced into the second chamber 81 through the gas inlet port (not shown) formed in the lid and the shower head 75. In addition, the gas exhaust unit is installed, and a specific processing, e.g., film formation, is performed while heating the chamber wall of the second chamber 81.

Specifically, as shown in FIG. 6, a gas exhaust unit is formed by installing the gas exhaust chamber 71 around the lower hole 52 of the first chamber 51, and connecting the valve or the vacuum pump to the line 74 connected to the gas exhaust chamber 71. The mounting table 72 having a heater is provided to be supported by a supporting member 73 extending vertically from the bottom portion of the gas exhaust chamber 71 into the second chamber 81 through the opening 82, and the shower head 75 for introducing a processing gas into the second chamber 81 is provided at the backside of the lid 55. Further, a processing gas is introduced into the second chamber 81 through the gas inlet port formed in the lid 55 and the shower head 75. The loading/unloading port 83 can be opened and closed by the gate valve G. An elevation rod 87 of the gate valve G is vertically moved through the hole 54 formed in the bottom portion of the first chamber 51. The gap between the elevation rod 87 and the bottom wall of the first chamber 51 is vacuum-sealed, and the bottom wall defining the space 53 is also vacuum-sealed.

Accordingly, the wall portion of the second chamber 81 is heated by, e.g., the heater 91, and the processing gas is introduced into the second chamber 81 from the shower head 75 while heating the wafer W on the mounting table 72. As a consequence, CVD film formation may be performed on the wafer W.

Hereinafter, an operation of the multi-chamber vacuum processing chamber configured as described above will be explained.

First, a wafer W is unloaded from the FOUP F connected to the loading/unloading port 8 by the transfer unit 16, and then loaded into the load-lock chamber 6 or 7. At this time, the inside of the load-lock chamber 6 or 7 is set to the atmospheric atmosphere and, then, the wafer W is loaded thereinto by opening the gate valve G2 to be mounted on the stage 41.

Next, the load-lock chamber is exhausted to vacuum until a pressure therein reaches a pressure in the transfer chamber 5. The wafer W is received by the support arm 14a or 14b of the transfer unit 12 by opening the gate valve G1. Then, the gate valve G of any one of the processing units 1 to 4 opens so that the wafer W can be loaded thereinto. Thereafter, a specific vacuum processing is performed on the wafer W.

Upon completion of the vacuum processing, the gate valve G opens, and the wafer W is unloaded from the processing unit by the support arm 14a or 14b of the transfer unit 12. Next, the gate valve G1 of the load-lock chamber 6 or 7 opens, and the wafer W is unloaded into the load-lock chamber. Then, the wafer W is mounted and cooled on the stage 41 having a cooling function to be cooled.

When the wafer W is unloaded, after completion of the cooling, a purge gas is supplied into the load-lock chamber 6 or 7 to set a pressure therein to the atmospheric pressure. Then the gate valve G1 opens, and the wafer W is unloaded into the loading/unloading chamber 8 of the atmospheric atmosphere to be accommodated in the FOUP F by the support arm 17 of the transfer unit 16.

In the present embodiment, in order to reduce cost, footprint, sealing or the like, the integrated chamber 61 is constituted by integrally forming the main body 5a of the transfer chamber 5 and the first chambers 51 of the processing units 1 to 4.

In the above configuration, in case of the hot wall type processing units 1 to 4 for heating the chamber wall itself, the integrated chamber 61 is entirely heated when the wall portions of the first chambers 51 are heated, which increases the number of heat insulating units of the transfer chamber 5 side and the number of heat resistant components. Conventionally, the processing units 1 to 4 are limited to either the cold wall type or the hot wall type, and it is not possible to selectively use the processing units 1 to 4 as the cold wall type or the hot wall type as desired.

On the other hand, in the present embodiment, the wall portions of the first chambers 51 constituting the integrated chamber 61 are provided with no heater, and each of the first chambers 51 is used as the chamber of the cold wall type processing unit for performing a specific processing such as film formation or the like. When any of the first chambers 51 needs to be used as the chamber of the hot wall type processing unit, the second chamber 81 is installed in the first chamber 51 in an adiabatic state.

In other words, when processing the wafer W in the cold wall type processing unit, the mounting table 72, and the shower head 75 are installed in the first chamber 51 and, further, the gas exhaust unit is installed. Then, the wafer W is mounted on the mounting table 72, and the first chamber 51 is set to a predetermined vacuum atmosphere by performing vacuum evacuation by the gas exhaust unit. In that state, the processing such as film formation or the like is performed on the wafer W while heating the wafer W by the heater in the mounting table 72.

Meanwhile, in the case of processing the wafer W in the hot wall type processing unit, the second chamber 81 having the heater 91 provided in the wall portion thereof is installed in the first chamber 51. Then, the mounting table 72, the shower head 75 and the like are installed in the second chamber 81 and, further, the gas exhaust unit is installed. Thereafter, the wafer W is mounted on the mounting table 72 and the inside of the second chamber 81 is set to a predetermined vacuum atmosphere by performing vacuum evacuation by the gas exhaust unit. At this time, the space 85 between the first chamber 51 and the second chamber 81 is set to vacuum, and the chamber wall is heated in a state where the first chamber 51 and the second chamber 81 are insulated from each other. Then, the predetermined processing such as film formation or the like is performed on the wafer W while heating the wafer W by the heater in the mounting table 72.

When the second chamber 81 is detachably installed in any of the first chambers 51 constituting the integrated chamber 61 and the processing is performed while using the second chamber 81 as the chamber of the hot wall type processing unit, the second chamber 81 is installed to be insulated from the first chamber 51 and the processing is performed in the second chamber. Accordingly, the transfer of heat of the second chamber 81 to the first transfer 51 is suppressed and the integrated chamber 61 is not entirely heated. Therefore, the number of heat insulating units of the transfer chamber 5 side and the number of heat resistant components are not increased.

When processing the wafer W in the cold wall type processing unit, the processing is performed in the first chamber 51 without installing the second chamber 81. When processing the wafer W in the hot wall type processing unit, the processing is performed in the second chamber 81 installed in the first chamber 51. Hence, the cold wall type and the hot wall type can be selectively used.

The present invention may be variously modified without being limited to the above embodiment. For example, in the above embodiment, the second chamber 81 is configured as the hot wall type chamber for heating the wall portion thereof. However, the present invention is not limited thereto and may be applied to, e.g., the case of cooling a wall portion of a chamber and reducing a gas discharge amount from the wall portion. The temperature of the wall portion of the chamber in the case of requiring cooling is different from that in the case of not requiring cooling. The present invention can be used even in such a case. If the cooling is performed at a low temperature of, e.g., about −30° C., the transfer chamber of the integrated chamber is adversely affected. However, if the second chamber is cooled as in the present invention, such problem does not occur.

In the above embodiment, the multi-chamber vacuum processing system having four processing units 1 to 4 has been described as an example. However, the number of processing units is not limited thereto. Moreover, the processing system of the present invention is not limited to a vacuum processing system.

The above embodiment has described the example in which the main body 5a of the transfer chamber 5 and the first chambers 51 of the processing units 1 to 4 constitute the integrated chamber 61. However, the present invention is not limited to the case of using the integrated chamber in view of selectively using the cold wall type and the hot wall type.

Although the above embodiment has described the processing unit in which the mounting table 72, the shower head 75 and the gas exhaust chamber 71 are provided in the first chamber 51 or the second chamber 81. However, this is only an example, and the present invention may be applied to various apparatuses without being limited thereto. For example, the processing unit may further include a plasma generation unit.

In the above, the example in which the first chamber 51 and the second chamber 81 are vacuum insulated has been described. However, the first chamber 51 and the second chamber 81 may be insulated by providing a heat insulation member therebetween. Moreover, when the main body 5a of the transfer chamber 5 and the first chambers 51 of the processing units are not integrally formed, the insulation is not necessary.

The substrate to be processed is not limited to a semiconductor wafer, and may also be a glass substrate for FPD or the like.

While the invention has been shown and described with respect to the embodiments, it will be understood by those skilled in the art that various changes and modification may be made without departing from the scope of the invention as defined in the following claims.

What is claimed is:

1. A processing system comprising:
a transfer chamber having therein a transfer unit for transferring a substrate, the transfer chamber being maintained in a vacuum state; and
at least one processing unit connected to the transfer chamber, the processing unit configured to perform a processing on a substrate,
wherein the processing unit includes:
a first chamber in which a first processing is performed on a substrate; and
a second chamber detachably installed in the first chambers, a second processing being performed on a substrate in the second chamber installed in the first chamber,
wherein wall portions of the first chamber and the second chamber are maintained at different temperatures.

2. The processing system of claim 1, wherein the first chamber and the transfer chamber are integrally formed; and the wall portion of the first chamber is not subjected to heating or cooling which inflicts thermal effect to the transfer chamber, and the wall portion of the second chamber is subjected to heating or cooling.

3. The processing system of claim 2, wherein when the second chamber is installed, the second chamber is insulated from the first chamber.

4. The processing system of claim 3, wherein when the second chamber is installed, the first chamber and the second chamber are separated from each other with a space therebetween, and vacuum insulated from each other by setting the space in a vacuum state.

5. The processing system of claim 1, wherein the first processing and the second processing are performed in a vacuum state.

6. A processing system comprising:
a transfer chamber having therein a transfer unit for transferring a substrate, the transfer chamber being maintained in a vacuum state; and
at least one processing unit connected to the transfer chamber, the processing unit configured to perform a processing on a substrate,
wherein the processing unit includes:
a first chamber in which a first processing is performed on the substrate in a state where a wall portion of the first chamber is not subjected to heating or cooling which inflicts thermal effect on the transfer chamber; and
a second chamber detachably installed in the first chamber, a second processing being performed on a substrate in the second chamber installed in the first chamber in a state where a wall portion of the second chamber is heated or cooled, and
wherein the first chamber is formed integrally with the transfer chamber, and the second chamber is installed in the first chamber in an adiabatic state.

7. The processing system of claim 6, wherein the first processing and the second processing are performed in a vacuum state; and the first chamber and the second chamber are separated from each other with a space therebetween when the second chamber is installed in the first chamber; and vacuum insulated from each other by setting the space in a vacuum state.
